(19) United States
(12) Patent Application Publication
(10) Pub. No.: US 2007/0095284 A1
(43) Pub. Date: May 3, 2007

(54) GAS TREATING DEVICE AND FILM FORMING DEVICE

(76) Inventors: Hachishiro IIZUKA, Nirasaki-shi (JP); Koichiro Kimura, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/562,661

(22) Filed: Nov. 22, 2006

Related U.S. Application Data
(63) Continuation of application No. PCT/JP05/10152, filed on Jun. 2, 2005.

(30) Foreign Application Priority Data
Jun. 4, 2004 (JP) 2004-167237

(51) Int. Cl. C23C 16/00

(52) U.S. Cl. 118/715

(57) ABSTRACT

A gas treating device includes a mounting base to support a substrate, a treatment container, a post mix type shower head, and a gas supply mechanism having a source gas flow path to supply a source gas to the shower head and an oxidizing gas supply path to supply an oxidizing gas to the shower head. The shower head includes a bottom surface which faces the substrate on the mounting base via a predetermined space, a groove formed in the bottom surface, a plurality of source gas discharge ports communicated with the source gas flow path, and bored in the bottom surface except the groove to discharge the source gas, and a plurality of oxidizing gas discharge ports communicated with the oxidizing gas flow path, and bored in the groove to discharge the oxidizing gas.

### CROSS-REFERENCE TO RELATED APPLICATIONS

This is a Continuation Application of PCT Application No. PCT/JP2005/010152, filed Jun. 2, 2005, which was published under PCT Article 21(2) in Japanese.

This application is based upon and claims the benefit of priority from prior Japanese Patent Application No. 2004-167237, filed Jun. 4, 2004, the entire contents of which are incorporated herein by reference.

### BACKGROUND OF THE INVENTION

1. Field of the Invention

The present invention relates to a gas treating device which separately and independently discharges a plurality of gases from a shower head to treat the gases, and a film forming device which forms a thin film on a substrate to be treated by a CVD method using such a shower head.

2. Description of the Related Art

In a semiconductor manufacturing process, a thin film made of various materials is formed on a semiconductor wafer (wafer hereinafter), and diversity/complexity has progressed in materials or combinations used for forming a thin film in response to diversity or the like of physical properties required of the thin film.

A recent focus of attention has been a Pb (Zr₁₋ₓTix)O₃ film (PZT film hereinafter) which has ferroelectricity as a capacitor material of a planar stack-type FeRAM and which is a crystal film of a perovskite structure, and development of a technology of generating a high-quality PZT film with good reproducibility has been advanced. For example, Jpn. Pat. Appln. KOKAI Publication No. 2000-260766 proposes chemical vapor deposition (CVD) which supplies a source gas and an oxidizing gas into a treatment container while heating a wafer therein to deposit a multielement metal oxide thin film such as PZT on the wafer.

A PZT deposition temperature is normally in a range of 500 to 650° C., and oxygen gas (O₂) is generally used for an oxidizing agent. However, depending on a device structure, a permissible PZT deposition temperature may be 500° C. or less. In the case of forming a film in a temperature range lower than normal, such as 500° C. or less, for example as described in Jpn. Pat. Appln. KOKAI Publication No. 2000-58526, nitrogen dioxide gas (NO₂) having a high oxidizing force is used as an oxidizing agent. According to this conventional technology, the NO₂ gas is supplied to a wafer in a treatment container by using a post mix type shower head.

However, physical properties (especially reactivity) vary among gases of different components. Consequently, when a gas discharge port is only bored in a shower head bottom surface formed to be planar as in the case of the conventional shower head, gas reactivity or uniform reaction may not be always achieved as desired.

Furthermore, in the case of forming a film by using a strong oxidizing agent such as NO₂ gas, a reaction product sticks to a peripheral wall of the gas discharge port of the shower head, and the stuck reaction product grows to gradually narrow the gas discharge port, causing gradual deterioration of uniformity and reproducibility of the formed film. The reaction product is peeled off from the peripheral wall of the discharge port to scatter as particles, creating a risk that these will stick to a wafer surface.

### BRIEF SUMMARY OF THE INVENTION

An object of the present invention is to provide a gas treating device capable of adjusting reaction or the like of gases of different kinds, and a film forming device. Another object of the present invention is to provide a film forming device capable of suppressing sticking of a reaction product to a compound forming gas discharge port of a shower head when a metal compound film is formed on a substrate based on gas characteristics, a source gas containing a metal, and a compound forming gas for forming a compound with the metal.

A first aspect of the present invention comprises, a gas treating device comprising a mounting base to support a substrate to be treated, a treatment container to surround the substrate to be treated on the mounting base, a shower head to separately and independently discharge a first gas and a second gas to the substrate to be treated on the mounting base, and a gas supply mechanism having a first gas flow path to supply the first gas to the shower head and a second gas supply path to supply the second gas to the shower head, characterized in that the shower head has: a bottom surface which faces the substrate to be treated on the mounting base via a predetermined space; a groove formed in the bottom surface; a plurality of first gas discharge ports communicating with the first gas flow path of the gas supply mechanism, and bored in the bottom surface except the groove to discharge the first gas; and a plurality of second gas discharge ports communicated with the second gas flow path of the gas supply mechanism, and bored in the groove to discharge the second gas.

A second aspect of the present invention comprises, a gas treating device comprising a mounting base to support a substrate to be treated, a treatment container to surround the substrate to be treated on the mounting base, a post mix type shower head arranged to face the substrate to be treated on the mounting base, and a gas supply mechanism having a first gas flow path to supply a first gas to the shower head and a second gas supply path to supply a second gas to the shower head, characterized in that the shower head has: a plurality of first gas discharge ports communicating with the first gas flow path of the gas supply mechanism to discharge the first gas; a plurality of second gas discharge ports communicating with the second gas flow path of the gas supply mechanism to discharge the second gas; a first surface arranged to face the substrate to be treated on the mounting base via a predetermined space and having the first gas discharge ports bored therein; and a second surface arranged to face the substrate to be treated on the mounting base via a predetermined space, and having the second gas discharge ports bored therein and a step with respect to the first surface.

A third aspect of the present invention comprises, a film forming device comprising a mounting base to support a substrate to be treated, a treatment container to surround the substrate to be treated on the mounting base, a shower head to separately and independently discharge a source gas and a compound forming gas to the substrate to be treated on the mounting base, and a gas supply mechanism having a first gas flow path to supply the source gas to the shower head and a second gas supply path to supply the compound forming gas to the shower head, the source gas containing a metal element and the compound forming gas containing a component element reacted with the metal element to form a compound, characterized in that the shower head has: a bottom surface which faces the substrate to be treated on the mounting base via a predetermined space; a groove formed in the bottom surface; a plurality of source gas discharge ports communicating with the first gas flow path of the gas supply mechanism, and bored in the bottom surface except the groove to discharge the source gas; and a plurality of compound forming gas discharge ports communicating with the second gas flow path of the gas supply mechanism, and bored in the groove to discharge the compound forming gas.

A fourth aspect of the present invention comprises, a film forming device comprising a mounting base to support a substrate to be treated, a treatment container to surround the substrate to be treated on the mounting base, a post mix type shower head arranged to face the substrate to be treated on the mounting base, and a gas supply mechanism having a source gas flow path to supply a source gas to the shower head and a compound forming gas supply path to supply a compound forming gas to the shower head, characterized in that the shower head has: a plurality of source gas discharge ports communicating with the source gas flow path of the gas supply mechanism to discharge the source gas; a plurality of compound forming gas discharge ports communicated with the compound forming gas flow path of the gas supply mechanism to discharge the compound forming gas; a first surface arranged to face the substrate to be treated on the mounting base via a predetermined space and having the source gas discharge ports bored therein; and a second surface arranged to face the substrate to be treated on the mounting base via a predetermined space, having the compound forming gas discharge ports bored therein, and positioned more apart from the substrate to be treated than the first surface.

In this specification, a “post mix type shower head” is a shower head of a type which has pluralities of different gas supply paths/discharge ports separately, and separately supplies different kinds of gases (e.g., source gas and oxidizing gas) into the treatment container via the gas supply paths/discharge ports, and mixes these gases after they are out of the different discharge ports.

The third and fourth aspects exemplify an oxidizing gas such as NO₂ as the compound forming gas. An organic metal gas is exemplified as the source gas. In the case of forming a PZT film, a Pb containing source gas, a Zr containing source gas, and a Ti containing source gas are mixed to be used as the organic metal gas. Specifically, Pb (dpm)₂, Ti (O-i-Pr)₂ (dpm)₂, and at least one of Zr (dpm)₄ and Zr (O-i-Pr)₂ (dpm)₂ can be used respectively as the Pb containing source gas, the Ti containing source gas, and the Zr containing source gas. These organic metal gases are thermally decomposed, and reacted with the oxidizing gas to form a PZT film on the substrate.

According to the first and second aspects, by adjusting the depth of the groove or the size of the step, reaching timing of the first and second gases to the substrate to be treated can be controlled, and reactivity thereof or the like can be properly adjusted.

According to the third aspect of the present invention, as the compound forming gas discharge port is more apart from the substrate than the source gas discharge port, a flow of the compound forming gas prevents flowing of the source gas to the compound forming gas discharge port (inside of the groove), making it difficult for the source gas to reach the compound forming gas discharge port. As a result, reaction is difficult to occur between the source gas and the compound forming gas around the compound forming gas discharge port, whereby sticking of a reaction product around the compound forming gas discharge port is suppressed. Moreover, as a sticking area of the reaction product is increased by an amount equal to the depth of the groove, a time until the compound forming gas discharge port is closed is greatly extended.

According to the fourth aspect of the present invention, as the second surface is more apart from the substrate than the first surface, a flow of the compound forming gas prevents flowing of the source gas to the compound forming gas discharge port (second surface), making it difficult for the source gas to reach the compound forming gas discharge port (second surface). Hence, as in the case of the third aspect, reaction occurs with difficulty between the source gas and the compound forming gas around the compound forming gas discharge port, whereby sticking of a reaction product around the compound forming gas discharge port is suppressed. Moreover, as a sticking area of the reaction product is increased by an amount equal to the step between the first and second surfaces, a time until the compound forming gas discharge port is closed is greatly extended.

### BRIEF DESCRIPTION OF THE SEVERAL VIEWS OF THE DRAWING

FIG. 1 is a sectional block diagram showing a film forming device according to an embodiment of the present invention.

FIG. 2 is a bottom diagram of a shower head used for the film forming device of FIG. 1.

FIG. 3 is a partially enlarged diagram showing an enlarged part of a bottom surface of the shower head of FIG. 2.

FIG. 4 is a partially cutout sectional diagram of a plate of the shower head showing a gas supply path and a discharge port.

FIG. 5A is a partially cutout enlarged sectional diagram of a shower head of a conventional device showing an enlarged gas discharge port.

FIG. 5B is a partially cutout enlarged sectional diagram of the shower head of the device of the present invention showing the enlarged gas discharge port.

FIG. 6A is a photo showing a state of an opening portion of an NO₂ gas discharge port in the shower head of the conventional device.

FIG. 6B is a photo showing a state of an opening portion of an NO₂ gas discharge port in the shower head of the device of the present invention.

### DETAILED DESCRIPTION OF THE INVENTION

Hereinafter, a best mode for carrying out the present invention will be described with reference to the accompanying drawings.

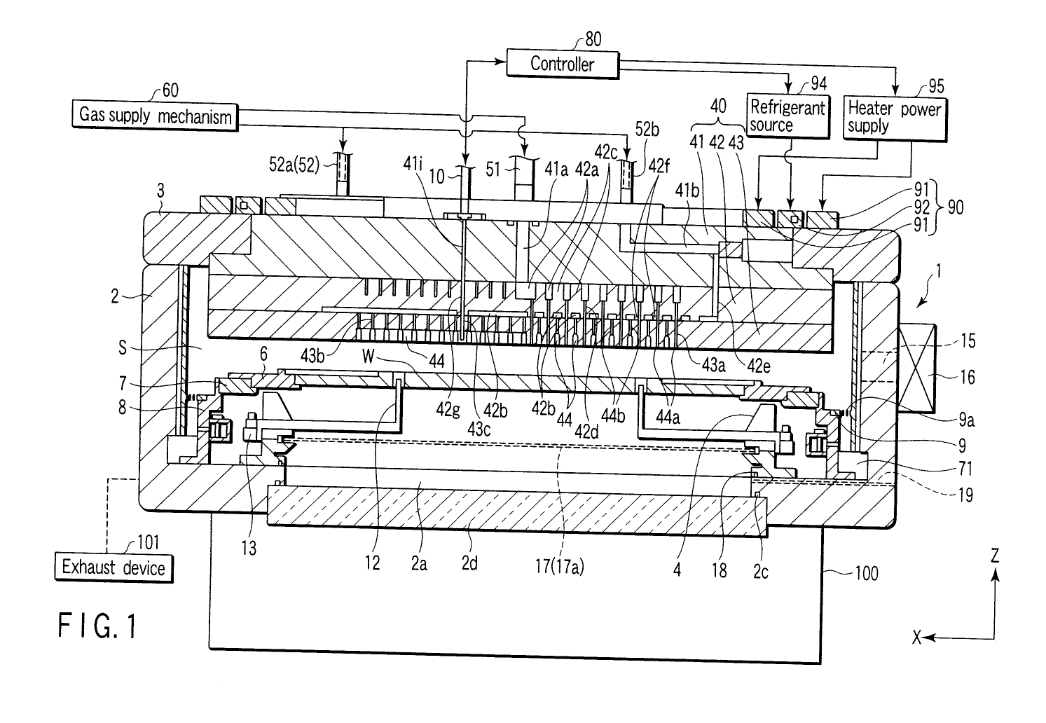

A film forming device of an embodiment includes a case 1 whose two-dimensional projection shape on an XZ plane is roughly rectangular. The case 1 is made of a metal such as aluminum or an aluminum alloy. A cylindrical treatment container 2 having a bottom is disposed in the case 1. As shown in FIG. 1, an opening 2a is formed in the bottom of the treatment container 2, and a transmission window 2d is fitted into the opening 2a from the outside. The transmission window 2d is made of transparent quarts, and a surface that abuts on the treatment container 2 is sealed by an O ring 2c to maintain airtightness in the treatment container 2. A lamp unit 100 is mounted to a bottom of the transmission window 2d, and a wafer W is heated by a heating lamp such as a halogen lamp (not shown). A lid 3 for supporting a shower head 40 is disposed to be opened/closed in an upper opening of the treatment container 2. When the lid 3 is closed, the wafer W on a mounting base 5 and the shower head 40 face each other via a predetermined space.

In the treatment container 2, a cylindrical shield base 8 is erected from the bottom of the treatment container 2. An annular base ring 7 is arranged in an opening above the shield base 8, an annular attachment 6 is supported on an inner peripheral side of the base ring 7, and the mounting base 5 supported by a step of an inner peripheral side of the attachment 6 to mount the wafer W is disposed. A baffle plate 9 (described below) is disposed outside the shield base 8.

A plurality of exhaust ports 9a are formed in the baffle plate 9. In an inner peripheral bottom of the treatment container 2, a bottom exhaust path 71 is disposed in a position around the shield base 8, and the treatment container 2 is uniformly exhausted by communicating the inside of the treatment container 2 with the bottom exhaust path 71 via the exhaust ports 9a of the baffle plate 9.

The bottom exhaust path 71 communicates with exhaust combining units (not shown) symmetrically arranged sandwiching the treatment container 2 in diagonal positions of the bottom of the case 1. This exhaust combining unit communicates with an upward exhaust path (not shown) disposed in a corner of the case 1, a downward exhaust path (not shown) arranged through the corner of the case 1 via a horizontal exhaust tube (not shown) disposed in an upper part of the case 1, and an exhaust device 101 arranged below the case 1.

A wafer entrance 15 communicating with a treatment space S is disposed in a side face of the case 1, and a load lock room (not shown) is connected through a gate valve 16 to the wafer entrance 15.

In a space surrounded by the mounting base 5, the attachment 6, the base ring 7, and the shield base 8, a cylindrical reflector 4 is erected from the bottom of the treatment container 2. This reflector 4 reflects heat rays emitted from the lamp unit 100 and guides them to the bottom surface of the mounting base 5 so that the mounting base 5 can be efficiently heated. A heating source is not limited to the aforementioned lamp. A resistive heater may be buried in the mounting base 5 to heat the same.

This reflector 4 includes, e.g., slits in three places, and lift pins 12 for lifting the wafer W from the mounting base 5 are arranged in positions corresponding to the slits to be elevated. Each lift pin 12 is integrally constituted of a pin portion and a support portion, supported by an annular holding member 13 disposed outside the reflector 4, and moved up and down by elevating the holding member 13 by an actuator (not shown). This lift pin 12 is made of a material to transmit the heat ray applied from the lamp unit 100, e.g., quartz or ceramics (e.g., Al₂O₃, AlN, SiC).

The lift pin 12 is raised from the mounting base 5 to a predetermined height to project when the wafer W is transferred. The lift pin 12 is pulled into the mounting base 5 when the wafer W supported by the lift pin 12 is mounted on the mounting base 5.

The reflector 4 is disposed in the bottom of the treatment container 2 below the mounting base 5. A gas shield 17 is mounted on an inner periphery of the reflector 4 so that its entire periphery can be supported. The gas shield 17 is made of a heat ray transmission material such as quartz or the like. A plurality of apertures 17a are bored in the gas shield 17.

A purge gas (e.g., inactive gas such as N₂ gas or Ar gas) is supplied from a purge gas supply mechanism through a purge gas flow path 19 to a space with the transmission window 2d below the gas shield 17. The purge gas flow path 19 is formed in the bottom of the treatment container 2 to be bored therein from gas supply openings 18 equally arranged in eight places in a lower part inside the reflector 4.

The purge gas thus supplied flows through the plurality of apertures 17a of the gas shield 17 into the backside of the mounting base 5, whereby a treatment gas from the shower head 40 is prevented from entering a space of the backside of the mounting base 5 to give damage such as deposition of a thin film on the transmission window 2d.

The shower head 40 is disposed above the mounting base 5 to face the same. The shower head 40 is made of a metal such as aluminum or an aluminum alloy. The shower head 40 includes a disk shower base 41, a disk gas diffusion plate 42, and a disk shower plate 43. The shower base 41 is formed so that its outer edge can be engaged with an upper part of the lid 3. The gas diffusion plate 42 is mounted in tight contact with a bottom surface of the shower base 41. The shower plate 43 is mounted to a bottom surface of the gas diffusion plate 42.

The shower base 41 is fixed to the lid 3 by screws (not shown). A bonded portion between the shower base 41 and the lid 3 is airtightly sealed by an O ring. The shower base 41 and the gas diffusion plate 42 are airghtightly sealed from each other by an O ring, and the shower base 41, the gas diffusion plate 42, and the shower plate 43 are fixed by screws.

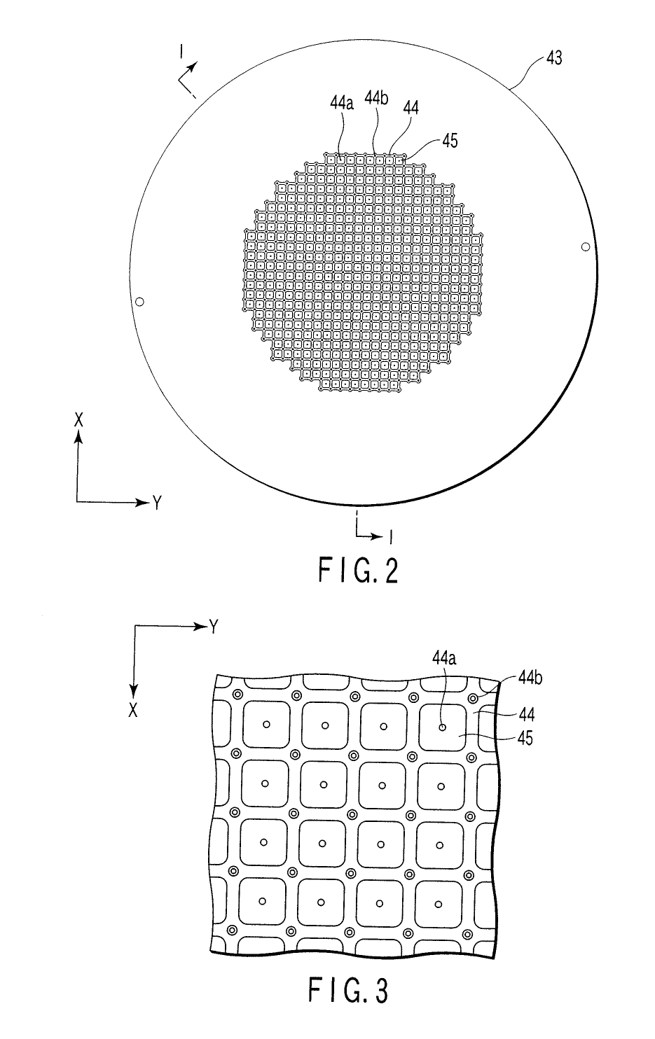

The shower base 41 includes a source gas introduction path 41a and a plurality of oxidizing gas introduction paths 41b. The source gas introduction path 41a is disposed in a center of the shower base 41, and a source gas introduction pipe 51 is connected thereto. The oxidizing gas introduction paths 41b are arranged in symmetric positions sandwiching the source gas introduction path 41a, and oxidizing gas branch pipes 52a and 52b of an oxidizing gas introduction pipe 52 are connected thereto. FIG. 1 showing the shower head is a sectional diagram cut along the line I-I of FIG. 2, in which left and right sides are asymmetric at a boundary of a center.

The source gas introduction pipe 51 and the oxidizing gas introduction pipe 52 are connected to a gas supply mechanism 60. The gas supply mechanism 60 includes a raw material tank (not shown) of each raw material and a carburetor (not shown). Liquid raw materials supplied from the raw material tanks, e.g., Pb (thd)₂, Zr (O-i-C₃H₇) (thd)₃, Ti (O-i-C₃H₇)₂ (thd)₂ dissolved by a solvent of butyl acetate or the like are mixed at a predetermined ratio (e.g., ratio to set Pb, Zr and Ti elements of PZT to a predetermined stoichiometric ratio). Then, the mixed liquid is vaporized by the carburetor to become a source gas, and supplied to the source gas introduction pipe 51. The gas supply mechanism 60 has an oxidizing gas source (not shown), and NO₂ gas is supplied from this oxidizing gas source to the pipe 52.

On an upper surface side of the gas diffusion plate 42, a source gas header 42a is formed as a concave space to diffuse a source gas. This source gas header 42a communicates with the source gas introduction path 41a to which the source gas introduction pipe 51 is connected. The source gas header 42a also communicates with the source gas path 42d penetrated the gas diffusion plate 42. A plurality of cylindrical projections 42c are concentrically disposed in the source gas header 42a. As a height of the cylindrical projection 42c is almost equal to a depth of the source gas header 42a, an upper end of the cylindrical projection 42c adheres to the lower surface of the shower base 41.

In a lower surface side of the gas diffusion plate 42, an oxidizing gas header 42b is formed as a concave space to diffuse an oxidizing gas. This oxidizing gas header 42b communicates through an oxidizing gas path 42e put through the gas diffusion plate 42 with the oxidizing gas introduction path 41b of the shower base 41. In the oxidizing gas header 42b, a plurality of cylindrical projections 42f are concentrically disposed. The source gas path 42d penetrates at least a part of the cylindrical projections 42f. As a height of the cylindrical projection 42f is almost equal to a depth of the oxidizing gas header 42b, a lower end of the cylindrical projection 42f adheres to the upper surface of the shower plate 43.

As described above, the shower base 41 and the gas diffusion plate 42 are brought into direct contact with each other by the plurality of cylindrical projections 42c, and the gas diffusion plate 42 and the shower plate 43 are brought into direct contact with each other by the plurality of cylindrical projections 42f. Thus, a heat conduction area is increased for the entire shower head 40 to improve heat responsiveness. As a result, the shower plate 43 can be quickly cooled or heated by cooling means 94 or heating means 95.

One of the cylindrical projections 42f in which the gas path 42d is formed is arranged to communicates with the source gas path 42d in a position of the source gas discharge port 43a of the shower plate 43. Gas paths 42d may be formed in all the cylindrical projections 42f.

As shown in FIGS. 2 to 4, the source gas discharge ports 43a and the oxidizing gas discharge ports 43b are alternately arranged adjacently to penetrate the shower plate 43. That is, the plurality of source gas discharge ports 43a are arranged in positions to overlap the source gas path 42d of the gas diffusion plate 42. Each of discharge ports 43a is communicated with the source gas path 42d. The plurality of oxidizing gas discharge ports 43b are arranged to be bored in apertures of the plurality of cylindrical projections 42f in the oxidizing gas header 42b of the gas diffusion plate 42.

In the shower plate 43 of the embodiment, the plurality of source gas discharge ports 43a connected to the source gas introduction pipe 51 are arranged in an outermost periphery. As shown in FIG. 3, inside thereof, the oxidizing gas discharge ports 43b and the source gas discharge ports 43a are alternately arranged equally.

As shown in FIGS. 2 to 4, grooves 44 are formed in the bottom surface (lower surface of the shower plate 43) of the shower head 40. A plurality of oxidizing gas discharge ports 44b are bored in bottom surfaces of the grooves 44. On the other hand, a plurality of source gas discharge ports 44a are bored in portions other than the grooves 44.

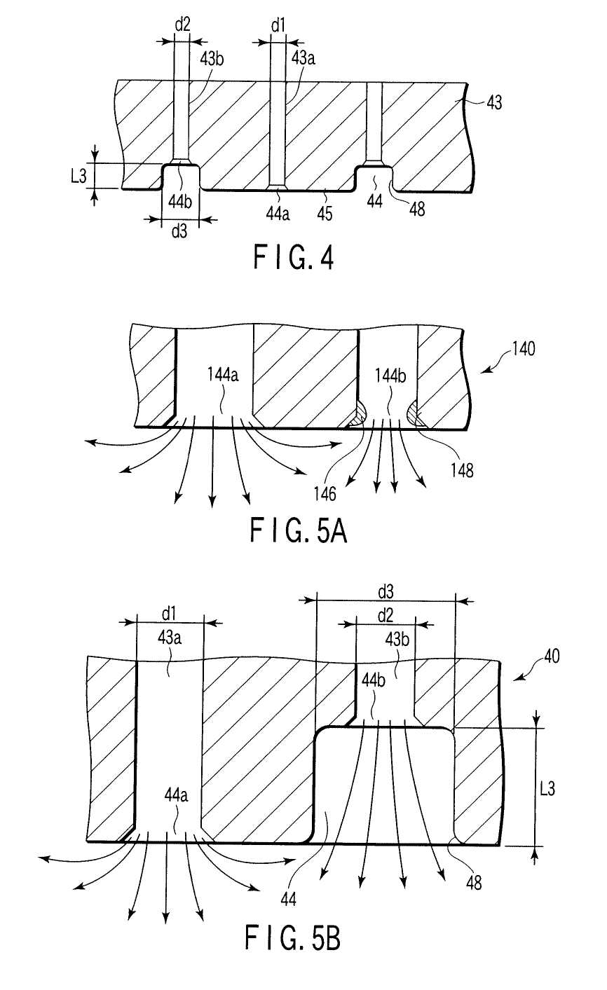

The grooves 44 have a lattice 2-dimensional projection shape, and includes longitudinal and horizontal grooves. The oxidizing gas discharge port 44b is positioned at an intersection between the longitudinal and horizontal grooves. The source gas discharge port 44a is disposed in a center of an island 45 partitioned by the grooves 44. That is, as shown in FIG. 4, the oxidizing gas discharge port 44b and the source gas discharge port 44a are formed on different surfaces (first and second surfaces) which have a step L3, and the oxidizing gas discharge port 44b is bored more apart from the wafer W than the source gas discharge port 44a. The step L3 (i.e., depth of the groove) is preferably set within a range of 0.5 to 10 mm. A width d3 of the groove 44 is preferably set within a range of 0.5 to 10 mm. According to the embodiment, the depth L3 (step) of the groove is set to about 2 mm, and the groove width d3 is set to about 3 mm.

As shown in FIGS. 4 and 5B, the island 45 to define the groove 44 has a corner 48 subjected to R processing (chamfering). In this case, a curvature radius of the roundish portion of the corner 48 is preferably set within a range of 0.1 to 1 mm. The source gas discharge port 44a and the oxidizing gas discharge port 44b can both be formed wider toward the ends as shown. A diameter d1 of the source gas discharge port 43a is preferably set within a range of 0.5 to 3 mm, and a diameter d2 of the oxidizing gas discharge port 43b is preferably set within a range of 0.5 to 3 mm. Diameters of the lower ends of the source gas discharge port 44a and the oxidizing gas discharge port 44b can be set within a range of 0.5 to 3 mm.

In the post mix type shower head 40, as the oxidizing gas discharge port 44b is bored separately from the source gas discharge port 44a, the source gas and the oxidizing gas are discharged separately and independently, and mixed in a space directly above the wafer W.

The embodiment has been described by way of example in which the source gas is introduced to the upper source gas diffusion space 42a and the oxidizing gas is introduced to the lower oxidizing gas diffusion space 42d. However, gas introducing positions can be changed in accordance with process conditions. That is, the oxidizing gas may be introduced to the upper source gas diffusion space 42a, and the source gas may be introduced to the lower oxidizing gas diffusion space 42b. A shape of the grooves 44 may be defined to be nonlattice by forming a 2-dimensional projection shape of the island 45 into a circle.

Thermocouple insertion ports 41i, 42g and 43c are overlapped in a thickness direction to penetrate the shower base 41, the gas diffusion plate 42, and the shower plate 43 which have been stacked together. Thermocouples 10 are inserted into these through-ports communicated with one another, a temperature of the lower surface of the shower plate 43 is detected, and its detection signal is input to a controller 80. As described below, the controller 80 and a temperature control mechanism 90 control a temperature of the shower head 40.

In the upper surface of the shower head 40, a plurality of annular heaters 91 are disposed, and the temperature control mechanism 90 constituted of a refrigerant flow path 92 through which a refrigerant such as cooling water is distributed is arranged between the heaters 91. A detection signal of the thermocouple 10 is input to the controller 80, the controller 80 outputs a control signal to a heater power source 95 and a refrigerant source 94 based on this detection signal, and feedback-controls energization of the temperature control mechanism 90 to the heater 91, or a temperature or a flow rate of a refrigerant distributed through the refrigerant flow path 92, whereby a temperature of the shower head 40, especially a surface temperature of the shower plate 43, can be controlled.

Next, an operation of the film forming device thus configured will be described.

First, the inside of the treatment container 2 is exhausted by a vacuum pump (not shown) via an exhaust path such as the bottom exhaust flow path 71 to a vacuum degree of, range of e.g., 66.65 to 1333 Pa, preferably 100 to 500 Pa.

In this case, a constant purge gas flow is formed in which a purge gas such as Ar is supplied from a carrier/purge gas supply source (not shown) through the purge gas flow path 19 and through the plurality of gas discharge openings 18 to the backside (bottom surface) of the gas shield 17, and this purge gas flows through the port 17a of the gas shield 17 into the backside of the mounting base 5, and flows through the apertures of the shield base 8 into the bottom exhaust flow path 71, thereby preventing damage such as deposition of a thin film or the like on the transmission window 2d positioned below the gas shield 17.

In the treatment container 2 of this state, the wafer W is conveyed through the gate valve 16 and the wafer entrance 15 by a robot hand mechanism or the like (not shown), the lift pin 12 held by the holding member 13 is raised by an actuator (not shown) so that its pin portion can project from the mounting base 5, the wafer W is mounted on the lift pin 12, and then the robot hand mechanism or the like (not shown) is retreated from the treatment container 2 to close the gate valve 16.

Next, the lift pin 12 is lowered to mount the wafer W on the mounting base 5, the lamp of the lamp unit 100 is lit to apply a heat ray through the transmission window 2d to the lower surface (backside) of the mounting base 5, thereby heating the wafer W mounted on the mounting base 5 to a temperature of 450° C. to 700° C., e.g., 500° C. The aforementioned lamp of the lamp unit 100 may be always lit for the purpose of shortening a temperature stable time, extending a lamp life, or the like.

At this time, the lower surface temperature of the shower plate 43 is detected by the thermocouple 10 based on its detection temperature, and the temperature control mechanism 90 is controlled by the controller 80 to execute temperature control of the shower head 40.

Next, a source gas prepared by mixing, e.g., Pb (thd)₂, Zr (O-i-C₃H₇) (thd)₃, and Ti (O-i-C₃H₇)₂ (thd)₂ at a predetermined ratio (e.g., ratio to set elements of Pb, Zr, Ti and the like of PZT to a predetermined stoichiometric ratio) and vaporized by a carburetor (not shown) is discharged and supplied from the plurality of source gas discharge ports 44a of the shower pate 43 of the bottom surface of the shower head 40 to the heated wafer W. An oxidizing gas such as NO₂ is discharged and supplied from the oxidizing gas discharge ports 44b. By thermal decomposition reaction or chemical reaction of the source and oxidizing gases, a thin film made of PZT is formed on the surface of the wafer W.

That is, the vaporized source gas that has come from the gas supply mechanism 60 is discharged and supplied together with a carrier gas from the source gas pipe 51 through the header 42a of the gas diffusion plate 42, the source gas path 42d, and the source gas discharge port 43a of the shower plate 43 and from the source gas discharge port 44a to the upper space of the wafer W. Similarly, the oxidizing gas supplied from the gas supply mechanism 60 is passed through the oxidizing gas pipe 52, the oxidizing gas branch pipes 52a and 52b, the oxidizing gas introduction path 41b of the shower base 41, and the oxidizing gas path 42e of the gas diffusion plate 42 to reach the header 42b, and passed through the oxidizing gas discharge port 43b of the shower plate 43 to be discharged and supplied from the oxidizing gas discharge port 44b to the upper space of the wafer W. Accordingly, the source gas and the oxidizing gas are separately supplied into the treatment container 2 not to be mixed in the shower head 40.

In this case, according to the conventional device, as shown in FIG. 5A, since the source gas discharge port 144a and the oxidizing gas discharge port 144b of the shower head 140 having almost equal gas discharge areas are bored on one and the same plane, the source gas easily reaches the oxidizing gas discharge port 144b to cause sticking of a reaction product 146 to the peripheral wall of the oxidizing gas discharge port 144b. The sticking of the reaction product 146 narrows or closes the oxidizing gas discharge port 144b, causing a problem of deterioration of thickness uniformity of a film or generation of particles.

On the other hand, according to the device of the embodiment, as shown in FIG. 5B, the groove 44 is formed in the lower surface of the shower plate 43, and the oxidizing gas discharge port 44b is bored in the groove 44, while the source gas discharge port 44a is bored in the portion other than the grooves 44. Thus, the openings of the source and oxidizing gas ports 44a and 44b are different in coordinate positions of a Z-axis direction. As a result, flowing of the source gas to the oxidizing gas discharge port 44b is prevented by the oxidizing gas flow, making it difficult for the source gas to reach the same.

Therefore, according to the present invention, reaction is difficult to occur between the source gas and the compound forming gas around the oxidizing gas discharge port 44b, whereby sticking of a reaction product around the oxidizing gas discharge port 44b is suppressed. Moreover, according to the present invention, as a sticking area of the reaction product is increased by an amount equal to the depth L3 (step) of the grooves 44, a time until the compound forming gas discharge port is closed can be greatly extended. According to the present invention, the groove only needs to be formed, and it is not necessary to change the positions of the ports of the shower head of the existing facilities.

A layout of grooves 44 is a lattice. Thus, all the grooves are continuous, diffusion of the oxidizing gas is high, and a nonuniform density of the oxidizing gas is prevented. As the oxidizing gas discharge ports 44b are disposed at the lattice intersections of the latticed grooves 44, it is possible to further improve diffusion of the gas discharged therefrom.

By setting the step (differential of height level) between the two kinds of gas discharge port opening surfaces, reaching timing of these gases can be controlled. As a result, it is possible to properly adjust reactivity thereof or the like.

The step L3 (depth of the groove) shown in FIG. 4 is preferably set within the range of 0.5 to 10 mm. Accordingly, reaching of the source gas to the oxidizing gas discharge port 44b can be effectively suppressed without any excessive costs. The island 45 to define the grooves 44 has the corner 48 subjected to the R processing (chamfering). Accordingly, sticking of a reaction product becomes difficult. From the standpoint of making more difficult the sticking of the reaction product, the curvature radius of the roundish portion is preferably set within 0.1 to 1 mm. Further, the source gas discharge port 44a and the oxidizing gas discharge port 44b can both be formed wider toward the ends as shown. Hence, the flowing of the source gas to the oxidizing gas discharge port 44b is suppressed, whereby the sticking of the reaction product to the oxidizing gas discharge port 44b can be made difficult.

When the temperature of the shower head 40 is controlled as described above, the lower surface temperature of the shower head 40 is preferably controlled within a range of 165° C. to 170° C. By controlling the temperature within this range, the sticking of the reaction product to the oxidizing gas discharge port 44b is made more difficult.

Next, an experiment that has checked effects of the present invention will be described.

According to this experiment, PZT films were formed on silicon wafers by using the conventional post mix type shower head and the post mix type shower head of the present invention, and a sticking state of a reaction product to an NO₂ gas discharge port peripheral wall of each shower head was visually checked. In the case of the conventional post mix type shower head, there was no step in a bottom surface. In the case of the post mix type shower head of the present invention, a latticed groove having a depth 2 mm was disposed in a bottom surface, an NO₂ gas discharge port was arranged in the groove portion, and a source gas discharge port was arranged in a portion other than the groove. Diameters of the NO₂ gas discharge ports were 0.7 mm for the conventional shower head, and 1.2 mm for the shower head of the present invention.

Deposition conditions were a mounting base temperature: 500° C., pressure: 133.3 Pa, an NO₂ gas flow rate: 400 mL/min, Pb (thd)₂ (liquid) flow rate: 0.13 mL/min, Zr (O-i-C₃H₇) (thd)₃ (liquid) flow rate: 0.27 mL/min, Ti (O-i-C₃H₇)₂ (thd)₂ (liquid) flow rate: 0.42 mL/min, deposition time: 850 sec.

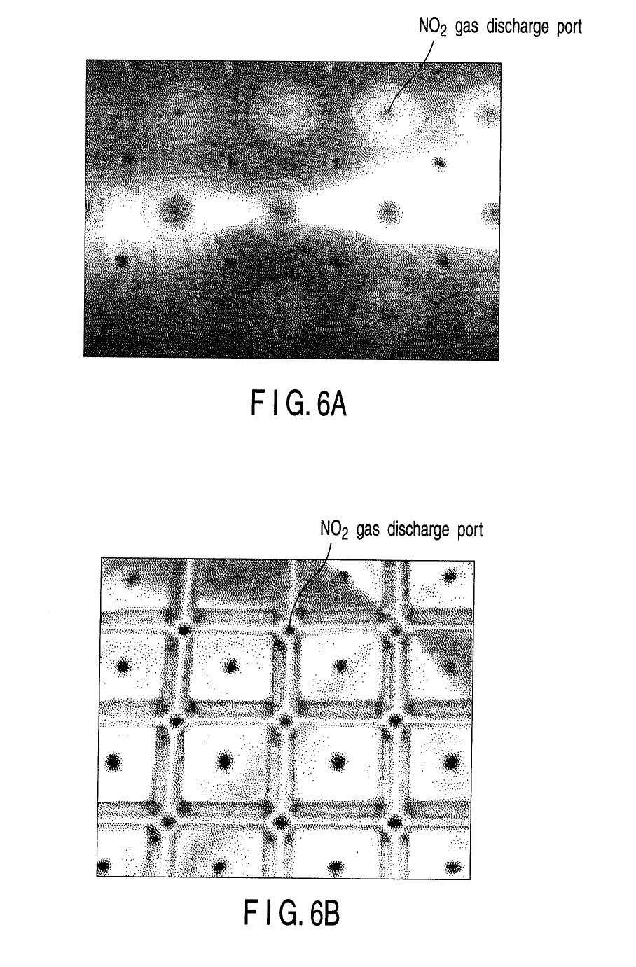

After 100 films were formed under the above conditions, shower head bottom surfaces were photographed, and they are shown in FIGS. 6A and 6B. In the case of the conventional shower head shown in FIG. 6A, a reaction product greatly stuck to the NO₂ gas discharge ports to close almost all the ports. On the other hand, in the case of the shower head of the present invention shown in FIG. 6B, almost no sticking of a reaction product to the NO₂ gas discharge ports was observed.

The present invention is not limited to the foregoing embodiment. Various changes can be made within its teachings. For example, the embodiment has been described by way of example in which the NO₂ gas is used as the oxidizing gas. However, an oxidizing gas such as 02 gas, N₂O gas, or 03 gas may be used. The invention can be applied when a gas other than the oxidizing gas is used as a compound forming gas to form another metal compound such as a nitride. The example of forming the PZT thin film has been described. However, the deposition is not limited to this. Deposition using another organic metal raw material such as a BST film (crystal film having a perovskite structure of Ba (Sr₁₋ₓTix)O₃), or deposition using a source gas containing a metal other than an organic raw material may be employed. The invention can be widely applied when gases of two kinds or more are used. Furthermore, the embodiment has been described by way of example of the film forming device of the thermal CVD. However, a film forming device using plasma, and other gas treating devices such as a plasma etching device may be employed. In the case of using the plasma, various waves such a high-frequency wave, and a microwave can be used as plasma sources. In the case of using a high-frequency plasma source, it can be applied to various methods such as capacitance coupled type plasma, inductive coupled type plasma (IPC), ECR plasma, and magnetron plasma.

According to the embodiment, the latticed grooves are formed so that all the grooves in the bottom surface of the shower head can be continuous. However, the groove shape is not limited to the lattice. Especially, the continuous formation of all the grooves improves uniformity of a gas density or the like. However, not all the grooves need to be formed continuously. A plurality of grooves having a plurality of compound forming gas discharge ports formed to be continuous may be formed. An example of this is a concentric circular groove. Needless to say, a groove may be disposed for each compound forming gas discharge port.

Additionally, the embodiment has been described by taking the example of the semiconductor wafer as the substrate to be treated. However, not limited to this, other substrates such as a glass substrate for a liquid crystal display may be used.

According to the present invention, as the sticking of the reaction product to the compound forming gas discharge port of the shower head is suppressed, its closing can be effectively prevented, whereby uniformity and reproducibility of the formed film can be improved, an operation rate of the device can be improved, and maintenance costs can be reduced. The present invention can be widely applied to a film forming device for performing desired deposition processing by supplying a treatment gas from a shower head disposed to face a substrate mounted on a mounting base and heated in a treatment container.

What is claimed is:

1. A gas treating device comprising a mounting base to support a substrate to be treated, a treatment container to surround the substrate to be treated on the mounting base, a shower head to separately and independently discharge a first gas and a second gas to the substrate to be treated on the mounting base, and a gas supply mechanism having a first gas flow path to supply the first gas to the shower head and a second gas supply path to supply the second gas to the shower head,
wherein the shower head has:
a bottom surface which faces the substrate to be treated on the mounting base via a predetermined space;
a groove formed in the bottom surface;
a plurality of first gas discharge ports communicated with the first gas flow path of the gas supply mechanism, and bored in the bottom surface except the groove to discharge the first gas; and
a plurality of second gas discharge ports communicated with the second gas flow path of the gas supply mechanism, and bored in the groove to discharge the second gas.

2. A gas treating device comprising a mounting base to support a substrate to be treated, a treatment container to surround the substrate to be treated on the mounting base, a post mix type shower head arranged to face the substrate to be treated on the mounting base, and a gas supply mechanism having a first gas flow path to supply a first gas to the shower head and a second gas supply path to supply a second gas to the shower head,
wherein the shower head has:
a plurality of first gas discharge ports communicating with the first gas flow path of the gas supply mechanism to discharge the first gas;
a plurality of second gas discharge ports communicating with the second gas flow path of the gas supply mechanism to discharge the second gas;
a first surface arranged to face the substrate to be treated on the mounting base via a predetermined space and having the first gas discharge ports bored therein; and
a second surface arranged to face the substrate to be treated on the mounting base via a predetermined space, and having the second gas discharge ports bored therein and a step with respect to the first surface.

3. A film forming device comprising a mounting base to support a substrate to be treated, a treatment container to surround the substrate to be treated on the mounting base, a shower head to separately and independently discharge a source gas and a compound forming gas to the substrate to be treated on the mounting base, and a gas supply mechanism having a first gas flow path to supply the source gas to the shower head and a second gas supply path to supply the compound forming gas to the shower head, the source gas containing a metal element and the compound forming gas containing a component element reacted with the metal element to form a compound,
wherein the shower head has:
a bottom surface which faces the substrate to be treated on the mounting base via a predetermined space;
a groove formed in the bottom surface;
a plurality of source gas discharge ports communicating with the first gas flow path of the gas supply mechanism, and bored in the bottom surface except the groove to discharge the source gas; and
a plurality of compound forming gas discharge ports communicating with the second gas flow path of the gas supply mechanism, and bored in the groove to discharge the compound forming gas.

4. The device according to claim 3, wherein the groove is continuously formed over the plurality of compound forming gas discharge ports.

5. The device according to claim 4, wherein the groove has a lattice-shaped two-dimensional projection form, and includes longitudinal and horizontal grooves.

6. The device according to claim 5, wherein the compound forming gas discharge ports are formed at intersections of the longitudinal and horizontal grooves.

7. The device according to claim 3, wherein a depth of the groove is in a range of 0.5 to 10 mm.

8. The device according to claim 2, wherein the step between the first and second surfaces is in a range of 0.5 to 10 mm.

9. A film forming device comprising a mounting base to support a substrate to be treated, a treatment container to surround the substrate to be treated on the mounting base, a post mix type shower head arranged to face the substrate to be treated on the mounting base, and a gas supply mechanism having a source gas flow path to supply a source gas to the shower head and a compound forming gas supply path to supply a compound forming gas to the shower head,
wherein the shower head has:
a plurality of source gas discharge ports communicating with the source gas flow path of the gas supply mechanism to discharge the source gas;
a plurality of compound forming gas discharge ports communicating with the compound forming gas flow path of the gas supply mechanism to discharge the compound forming gas;
a first surface arranged to face the substrate to be treated on the mounting base via a predetermined space and having the source gas discharge ports bored therein; and
a second surface arranged to face the substrate to be treated on the mounting base via a predetermined space, having the compound forming gas discharge ports bored therein, and positioned more apart from the substrate to be treated than the first surface.

10. The device according to claim 9, further comprising a temperature control mechanism to control a temperature of the shower head.

11. The device according to claim 9, wherein the compound forming gas is an oxidizing gas.

12. The device according to claim 11, wherein the oxidizing gas is NO₂ gas.

13. The film forming device according to claim 9, wherein the source gas is an organic metal gas.

14. The film forming device according to claim 13, wherein the organic metal gas contains Pb (dpm)₂ and Ti (O-i-Pr)₂ (dpm)₂ and at least one of Zr (dpm)₄ and Zr (O-i-Pr)₂ (dpm)₂ to be thermally decomposed and reacted with the oxidizing gas to form a PZT film.
